(19) United States
(12) Patent Application Publication
(10) Pub. No.: US 2026/0007082 A1
(43) Pub. Date: Jan. 1, 2026

(54) HIGH-PERFORMANCE PHOTOACTIVE SYNAPTIC DEVICE USING TWO-DIMENSIONAL FERROELECTRIC SEMICONDUCTOR WITH ASYMMETRIC ENERGY BAND STRUCTURE

(71) Applicant: THE INDUSTRY & ACADEMIC COOPERATION IN CHUNGNAM NATIONAL UNIVERSITY (IAC), Daejeon (KR)

(72) Inventors: Young-Jun YU, Daejeon (KR); Seok-Ju KANG, Daejeon (KR); Oh Hun GWON, Daejeon (KR); Wonzee JUNG, Daejeon (KR)

(73) Assignee: THE INDUSTRY & ACADEMIC COOPERATION IN CHUNGNAM NATIONAL UNIVERSITY (IAC), Daejeon (KR)

(21) Appl. No.: 19/059,041

(22) Filed: Feb. 20, 2025

(30) Foreign Application Priority Data
Jun. 27, 2024 (KR) 10-2024-0084834

(51) Int. Cl. H10N 70/20; H10B 63/00; H10N 70/00

(52) U.S. Cl. CPC H10N 70/257; H10B 63/00; H10N 70/25; H10N 70/253; H10N 70/8825

(57) ABSTRACT

Proposed is a high-performance photoactive neuromorphic synaptic device using a two-dimensional ferroelectric semiconductor with an asymmetric energy band structure, the synaptic device including a gate electrode layer, a buffer insulating layer arranged on the gate electrode layer, a channel layer arranged on the buffer insulating layer, a source electrode of a conductor arranged on the channel layer, and a drain electrode of a conductor arranged on the channel layer, and spaced apart from the source electrode, wherein the channel layer is made of the two-dimensional ferroelectric semiconductor, the buffer insulating layer is made of an insulating material having a lower dielectric constant than that of the channel layer, the gate electrode layer is configured to control an electric field of the channel layer by an applied electrical bias, and the photoactive neuromorphic synaptic device increases a Fermi level as increased electron-hole pairs.

### CROSS REFERENCE TO RELATED APPLICATION

The present application claims priority to Korean Patent Application No. 10-2024-0084834, filed Jun. 27, 2024, the entire contents of which are incorporated herein for all purposes by this reference.

### STATEMENT REGARDING GOVERNMENT SPONSORED RESEARCH

This invention is the result of research supported by the National Research Foundation of Korea (NRF) grant funded by the Korean government (MSIT) (RS-2022-NR070130), also supported by the Institute of Information & Communications Technology Planning & Evaluation (IITP) grant funded by the Korea government (MSIT) (RS-2021-II211552), and further supported by Basic Science Research Program through the National Research Foundation of Korea (NRF) funded by the Ministry of Education (RS-2020-NR049597).

### STATEMENT REGARDING PRIOR DISCLOSURES BY THE INVENTORS

This invention has been published in the NANO-MICRO Small: Volume 20, Issue 22, on Jan. 11, 2024.

### BACKGROUND OF THE INVENTION

### Field of the Invention

The present disclosure relates to a high-performance photoactive neuromorphic synaptic device using a ferroelectric semiconductor with an asymmetric energy band structure and, more particularly, to a technology that increases a Fermi level by illuminating a two-dimensional ferroelectric semiconductor with light, stabilizes an induced polarization state by enhancing the formation of an internal spontaneous electric field, and improves the linearity of a weight depression process of the synaptic device, thereby improving a pattern recognition rate of an artificial neural network circuit.

### Description of the Related Art

As semiconductor technology has developed, the speed and capacity of CPUs, memory, etc. have increased, and the spread of the Internet using wired and wireless communication has rapidly increased. With such development of information technology (IT), related industries such as e-commerce have grown rapidly. In addition, as artificial intelligence (AI) technology has emerged, large amounts of data are processed more quickly, and accordingly, a problem of increasing power consumption occurs.

Conventional computer systems use the von Neumann architecture where computation and memory are separated, causing problems that a lot of electric power is consumed and bottlenecks occur when the large amounts of data are processed. To solve these problems, neuromorphic computing technology is being studied, which mimics the efficient computational processing mechanism of biological neural networks. It is predicted that when commercialized, the neuromorphic computing technology will be able to perform deep learning computation at a speed that is 3,000 times faster than that of the latest CPU/GPU.

In order to implement neuromorphic computing, the functions of neurons and synapses constituting a nervous system are first mimicked by using semiconductor devices. Next, when these devices are integrated in an array form, a neuromorphic computing system optimized for matrix multiplication operations is able to be produced. In particular, synaptic devices are responsible for the core process of information transmission in the neuromorphic computing system, so developing the high-performance synaptic devices is the most important aspect in developing neuromorphic devices.

Synaptic devices should have variable resistance properties and non-volatile properties to mimic biological synapses. In addition, the synaptic devices should be able to change the weight of each synapse consistently according to a voltage applied from outside. Devices with the properties of resistors and memory are called memristors, including resistive RAM (ReRAM), Phase Change RAM (PCRAM), Ferroelectric RAM (FeRAM), etc.

Early synaptic devices are mainly two-terminal devices having a crossbar array structure, and the electrical properties of synapses are implemented by appropriately forming a CMOS circuit for combining multiple silicon-based transistors, but there are limitations in power consumption and the degree of integration. To overcome these limitations, a three-terminal synaptic transistor device that uses a ferroelectric semiconductor as an active layer is being studied.

The three-terminal synaptic transistor receives a signal transmitted from a presynaptic neuron through a source electrode and transmits the signal to a postsynaptic neuron through a drain electrode. When a gate voltage is controlled by using a gate electrode, which is the third electrode, lower power consumption and higher reliability is able to be secured during signal transmission compared a two-terminal memristor device.

Synapses have synaptic plasticity. The synaptic plasticity refers to the strengthening or weakening of the synapses over time in response to the increase or decrease in activity. The phenomena showing the synaptic plasticity include long-term potentiation (LTP) and long-term depression (LTD). The Long-term potentiation (LTP) is a phenomenon in which synaptic activation is enhanced by repeated stimulation, resulting in continuous enhancement of signal transmission, while long-term depression (LTD) is a phenomenon in which the activation efficiency of the synapses is decreased in response to repeated stimulation.

The three-terminal synaptic device may mimic excitatory postsynaptic current (EPSC) and inhibitory postsynaptic current (IPSC) depending on the type of presynaptic spike pulse voltage applied to a gate electrode. When continuous voltage pulses are input, the excitatory postsynaptic current (EPSC) and inhibitory postsynaptic current (IPSC) gradually increase or decrease, which may be used to implement synaptic plasticity.

A three-terminal ferroelectric-based synaptic device may increase a conductivity ratio (i.e., a dynamic range) of a synapse, allowing selection of various weights, so it is advantageous in parallel computation. However, this synaptic device exhibits the properties of rapid changes in a distribution ratio of polarization corresponding to an up or down direction of a ferroelectric material depending on the direction of an electric field, which is formed perpendicular to planes of ferroelectric stacks by a series of gate voltage pulses. This causes a problem in that linearity in the driving of a series of weight depression updates is decreased.

Meanwhile, conventional ferroelectrics, such as lead zirconate titanate (PbZrTiO₃), strontium bismuth tantalate (SrBi₂Ta₂O₉), and bismuth iron oxide (BiFeO₃), have a three-dimensional bonding structure, causing non-covalent surface defects, so when reducing the thicknesses thereof to a nanometer level, the conventional ferroelectrics exhibits their properties that greatly reduce memory performance because inducing ferroelectric polarization becomes difficult due to an undergone surface oxidation process and the like. Accordingly, it is required to develop a neuromorphic synaptic device using a two-dimensional ferroelectric semiconductor having improved oxidation stability and reliable operability even at the nanometer thickness because of using a ferroelectric material without inherent surface defects through a two-dimensional atomic bonding structure.

Korean Patent Application Publication No. 10-2023-0012964 published on Jan. 26, 2023 discloses a technology relating to the “SYNAPTIC DEVICE, RESERVOIR COMPUTING DEVICE INCLUDING THE SYNAPTIC DEVICE, AND RESERVOIR COMPUTING METHOD USING THE COMPUTING DEVICE”. The disclosed synaptic device includes a substrate and a plurality of unit cells on the substrate. Each of the unit cells includes a channel layer, and first and second electrodes intersecting the channel layer. The first electrode and the second electrode are spaced apart from each other to define a gap area exposing a part of the channel layer. The channel layer includes a two-dimensional semiconductor material or a two-dimensional ferroelectric material. The disclosed synaptic device exhibits synaptic plasticity and has resistance conversion plasticity opposing with respect to electrical signals and optical signals.

However, a technology for increasing the linearity of weight potentiation and weight depression according to Fermi level increase in a ferroelectric semiconductor has not yet been specifically disclosed.

### Documents of Related Art

(Patent Document 1) KR 10-2023-0012964 A (Jan. 26, 2023)

### SUMMARY OF THE INVENTION

An objective of the present disclosure is to provide a synaptic device that uses a ferroelectric material having the properties of semiconductor having a two-dimensional structure without structurally unsaturated bonds, so that oxidation stability in the air is improved and reliable operability is secured even at a nanometer thickness.

Another objective of the present disclosure is to provide a neuromorphic synaptic device capable of inducing a spontaneous internal electric field by illuminating the device with light in a visible light range, so as to secure a Fermi level increase and multilevel polarization states, thereby enhancing memory-based performance.

A yet another objective of the present disclosure is to provide a neuromorphic synaptic device configured to enhance a recognition rate of an artificial neural network circuit by compensating linearity decrease in weight potentiation and weight depression, which are caused by rapid polarization changes of a ferroelectric material.

The problems to be solved by the present disclosure are not limited to the problems described above, and other problems not described herein will be clearly understood by those skilled in the art from the description below.

According to one aspect of the proposed disclosure, there is provided a high-performance photoactive neuromorphic synaptic device using a two-dimensional ferroelectric semiconductor with an asymmetric energy band structure, the synaptic device including: a gate electrode layer; a buffer insulating layer arranged on the gate electrode layer; a channel layer arranged on the buffer insulating layer; a source electrode of a conductor arranged on the channel layer; and a drain electrode of a conductor arranged on the channel layer, and spaced apart from the source electrode. According to an additional aspect, the synaptic device may further include a barrier insulating layer arranged between the gate electrode layer and the buffer insulating layer.

The channel layer may be made of the two-dimensional ferroelectric semiconductor, the buffer insulating layer may be made of an insulating material having a lower dielectric constant than that of the channel layer, and the gate electrode layer may be configured to control an electric field in a vertical direction of the channel layer by an applied electrical bias.

According to an additional aspect, the channel layer may be composed of a two-dimensional transition metal dichalcogenide or a two-dimensional post-transition metal dichalcogenide.

According to an additional aspect, the channel layer may be composed of either In₂Se₃ or Bi₂O₂Se.

According to an additional aspect, the barrier insulating layer and the buffer insulating layer may be composed of either hexagonal boron nitride (hBN) or an oxide.

According to an additional aspect, the barrier insulating layer may be composed of an oxide, and the buffer insulating layer may be composed of hexagonal boron nitride (hBN).

According to an additional aspect, the gate electrode layer may be composed of either a metal or a highly doped semiconductor, and the gate electrode layer may have a work function higher than that of the channel layer.

According to an additional aspect, the gate electrode layer may be configured to control directions and magnitudes of polarization in the vertical direction of the channel layer by the applied electrical bias.

According to an additional aspect, the channel layer may generate electron-hole pairs by absorbing light in a range of visible light or ultraviolet light, and generate the internal electric field according to increase of a Fermi level.

According to another aspect of the proposed disclosure, there is provided an artificial intelligence module using a high-performance photoactive neuromorphic synaptic device using a two-dimensional ferroelectric semiconductor with an asymmetric energy band structure, the artificial intelligence module including: the synaptic device; and a light illumination device for illuminating light in a range of visible light or ultraviolet light toward a channel layer of the synaptic device.

According to an additional aspect, pulses input to a gate electrode of the neuromorphic synaptic device may include: a first pulse width in a weight potentiation section by long-term potentiation (LTP); and a second pulse width different from the first pulse width in a weight depression section by long-term depression (LTD).

According to another aspect of the proposed disclosure, there is provided a method of designing an artificial intelligence module using a high-performance photoactive neuromorphic synaptic device using a two-dimensional ferroelectric semiconductor with an asymmetric energy band structure, the method including: preparing the synaptic device; determining a pulse amplitude of a gate voltage spike (V_{GS}) on the basis of a ratio (Gₘₐₓ/Gₘᵢₙ, a dynamic range) of maximum conductance to minimum conductance; and determining a pulse width of the gate voltage spike used in processes of long-term potentiation (LTP) and long-term depression (LTD) based on a relaxation process of postsynaptic current (PSC).

According to an additional aspect, the determining of the pulse amplitude of the gate voltage spike (V_{GS}) may determine the pulse amplitude of the gate voltage spike (V_{GS}) based on the ratio (Gₘₐₓ/Gₘᵢₙ) of the maximum conductance to the minimum conductance that change in a case of illuminating a channel layer of the synaptic device with light.

The high-performance photoactive neuromorphic synaptic device using the ferroelectric semiconductor with the asymmetric energy band structure according to the present disclosure uses the ferroelectric material such as indium selenide (α-In₂Se₃) having the properties of semiconductor in the two-dimensional structure without structurally unsaturated bonds, thereby having improved oxidation stability in the air and reliable operability even at the nanometer thickness.

Furthermore, according to the present disclosure, the spontaneous internal electric field is induced by illuminating the device with light in the visible light range, so that the Fermi level increase and multilevel polarization states are secured, thereby enhancing the memory-based performance.

In addition, the synaptic device according to the present disclosure may enhance the recognition rate of the artificial neural network circuit by compensating the linearity decrease in the weight potentiation and weight depression due to the rapid polarization changes of the ferroelectric material.

### BRIEF DESCRIPTION OF THE DRAWINGS

FIG. 1 is a cross-sectional view schematically illustrating a main configuration of a high-performance photoactive neuromorphic synaptic device using a ferroelectric semiconductor with an asymmetric energy band structure according to an exemplary embodiment.

FIGS. 2A to 2E are conceptual views illustrating crystal structures and polarization phenomena of the ferroelectric material used in the synaptic device according to the exemplary embodiment.

FIGS. 3A and 3B are graphs illustrating optical properties of the ferroelectric material used in the synaptic device according to the exemplary embodiment.

FIG. 4 is a photograph taken from above with a microscope for the neuromorphic synaptic device according to the exemplary embodiment.

FIG. 5 is a graph illustrating results of source-drain current I_{DS} when measured directly in dark and when measured directly under illumination with visible light in response to control gate voltage V_{G} of the neuromorphic synaptic device according to the exemplary embodiment.

FIGS. 6A and 6B are graphs illustrating electrical responses to light stimulation of the neuromorphic synaptic device according to the exemplary embodiment.

FIGS. 7A and 7B are graphs illustrating electrical retention properties over time for a gate voltage pulse V_{GS} when the neuromorphic synaptic device is in a dark state or is illuminated with visible light according to the exemplary embodiment.

FIGS. 8A and 8B are surface photographs showing a topography obtained through an optical microscope and an atomic force microscope of a structure in which α-In₂Se₃ is stacked on hBN according to the exemplary embodiment.

FIGS. 9A to 9C are images and comparative graph illustrating plane potential and contact potential difference distributions of a structure in which the α-In₂Se₃ is stacked on the hBN as described in FIGS. 8A and 8B, the image and comparative graph being obtained by measurement under illumination with visible light or measurement in a dark state by a scanning Kelvin probe microscope, according to the exemplary embodiment.

FIGS. 10A to 10D are graphs illustrating an energy band structure of an α-In₂Se₃ channel layer in the neuromorphic synaptic device and an energy state distribution of electrons and holes according to exciton increase in the channel layer according to the exemplary embodiment.

FIG. 11 is a band diagram illustrating energy levels of each layer of the neuromorphic synaptic device before contact according to the exemplary embodiment.

FIGS. 12A and 12B are band diagrams each illustrating an equilibrium state energy level measured in a dark state or at time of illumination with visible light after each layer of the neuromorphic synaptic device is in contact according to the exemplary embodiment.

FIGS. 13A and 13B are graphs illustrating properties of continuous weight potentiation and weight depression, in a dark state and at time of illumination with visible light, as measured by high gate pulse amplitude of the neuromorphic synaptic device according to the exemplary embodiment.

FIGS. 14A and 14B are graphs illustrating properties of continuous weight potentiation and weight depression, in a dark state and at time of illumination with visible light, as measured by optimal gate pulse amplitude of the neuromorphic synaptic device according to the exemplary embodiment.

FIG. 15 is a graph comparing the properties of continuous weight potentiation and weight depression that change depending on changes in measurement conditions for gate pulse voltage of the neuromorphic synaptic device according to the exemplary embodiment.

FIG. 16 is a simulation graph illustrating recognition accuracy of MNIST (Modified National Institute of Standards and Technology) handwritten digit patterns according to the number of training times for high gate pulse voltage of the neuromorphic synaptic device according to the exemplary embodiment.

FIG. 17 is a simulation graph illustrating recognition accuracy of MNIST handwritten digit patterns according to the number of training times for optimal gate pulse voltage of the neuromorphic synaptic device according to the exemplary embodiment.

FIG. 18 is a schematic diagram illustrating a configuration of an artificial neural network module using neuromorphic synaptic devices according to the exemplary embodiment.

FIG. 19 is a flowchart illustrating a method of designing an artificial neural network module using neuromorphic synaptic devices according to the exemplary embodiment.

### DETAILED DESCRIPTION OF THE INVENTION

The above-described and additional aspects are embodied through exemplary embodiments described with reference to the attached drawings. It is understood that components of each exemplary embodiment may be combined in various ways with the components within the exemplary embodiments or components of other exemplary embodiments, as long as there is no other description or contradiction therebetween. The terms or words used in the present specification and claims should be interpreted as meanings and concepts corresponding to the description or proposed technical idea of the present disclosure on the basis of the principle that inventors may properly define the concept of terms or words in order to best describe their disclosures. In the present specification, a module or part may be implemented by using a set of program instructions stored in a memory so as to be executed by a computer or processor, or a set of electronic components or circuits such as ASIC or FPGA, so as to perform such instructions. In addition, the operation of each module or part may be performed by one or a plurality of processors or devices. Components that are marked with identical or similar symbols perform identical or similar functions, so descriptions thereof may be omitted. For components with drawing numerals having omitted description thereof, reference may be made to the previously described description of components having the identical or similar symbols.

Hereinafter, preferred exemplary embodiments of the present disclosure will be described in detail with reference to the accompanying drawings.

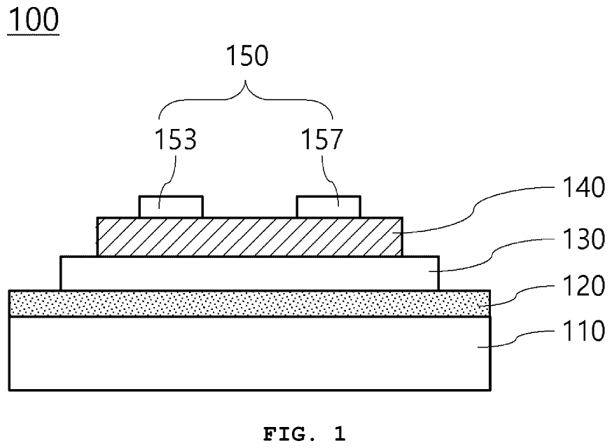

FIG. 1 is a cross-sectional view schematically illustrating a main configuration of a high-performance photoactive neuromorphic synaptic device using a two-dimensional ferroelectric semiconductor with an asymmetric energy band structure according to an exemplary embodiment.

According to one aspect of the proposed disclosure, the high-performance photoactive neuromorphic synaptic device 100 using the ferroelectric semiconductor with the asymmetric energy band structure includes a gate electrode layer 110, a buffer insulating layer 130, a channel layer 140, and a plurality of electrodes 150. According to an additional aspect, the synaptic device 100 may further include a barrier insulating layer 120.

The gate electrode layer 110 may serve as a substrate that supports or forms the buffer insulating layer 130 or the barrier insulating layer 120. The gate electrode layer 110 may be composed of either a metal with excellent conductivity or a highly doped semiconductor. For example, the gate electrode layer 110 may be composed of a metal such as aluminum (Al), copper (Cu), or gold (Au). As another example, the gate electrode layer 110 may be composed of a p-type, highly doped silicon (p⁺⁺ Si) semiconductor. The gate electrode layer 110 is composed of a conductive material having a work function higher than that of the channel layer. The gate electrode layer 110 forms a Schottky contact by contacting the buffer insulating layer 130 or the barrier insulating layer 120.

The barrier insulating layer 120 is positioned between the gate electrode layer 110 and the buffer insulating layer 130. The barrier insulation layer 120 may be composed of an insulating material. For example, the barrier insulating layer 120 may be composed of either 2D hexagonal boron nitride (hBN) or any one of oxides such as silicon dioxide (SiO₂), Al₂O₃, HfO₂, and ZrO₂. In a case where a highly doped silicon semiconductor is used in the gate electrode layer 110, it is preferable to use silicon dioxide (SiO₂) as the barrier insulating layer 120.

The buffer insulating layer 130 is positioned on the gate electrode layer 110. In a case where the barrier insulating layer 120 is present on the gate electrode layer 110, the buffer insulating layer 130 is positioned on the barrier insulating layer 120. The buffer insulating layer 130 has insulating properties and may be composed of a material having a low dielectric constant and a small number of charge trap sites. For example, the buffer insulating layer 130 may be composed of any one of 2D insulators such as hexagonal boron nitride (hBN) and hexagonal boron carbon nitride (BCN).

The channel layer 140 is positioned on the buffer insulation layer 130. The channel layer is made of a ferroelectric semiconductor, the buffer insulating layer is made of an insulating material having a lower dielectric constant than that of the channel layer, and the gate electrode layer controls an electric field applied to the channel layer by an applied electrical bias. According to an additional aspect, the channel layer 140 may be composed of a two-dimensional transition metal and a post-transition metal-based dichalcogenide compound. For example, the channel layer 140 may be composed of either indium selenide (In₂Se₃) or bismuth oxyselenide (Bi₂O₂Se). The channel layer 140 is configured to generate electron-hole pairs by absorbing light in a range of visible light or ultraviolet light, and to strengthen and generate the internal electric field according to increase of a Fermi level.

In a variation of the exemplary embodiment, a barrier insulating layer 120 may be composed of silicon dioxide (SiO₂), and a buffer insulating layer 130 may be composed of hexagonal boron nitride (hBN). When such a structure is used, a channel layer may operate more stably.

According to an additional aspect, the gate electrode layer 110 is configured to control the polarization of the channel layer 140 by an applied electrical bias. That is, the polarization of the channel layer 140 may be controlled by a magnitude and a sign of a gate voltage applied through the gate electrode layer 110.

A postsynaptic electrode 150 is formed on the channel layer. The postsynaptic electrode 150 may form a Schottky contact by contacting the channel layer. The postsynaptic electrode 150 includes a source electrode 153 and a drain electrode 157. The source electrode 153 is positioned on the channel layer 140 and is composed of a conductor. The drain electrode 157 is positioned on the channel layer 140 and is composed of a conductor. The source electrode 153 and the drain electrode 157 are spaced apart from each other, so the current flowing between the source electrode 153 and the drain electrode 157 flows through the channel layer 140.

The synaptic device 100 receives input of a presynaptic signal from a presynaptic neuron through the gate electrode layer 110 and outputs a postsynaptic current through the postsynaptic electrode 150.

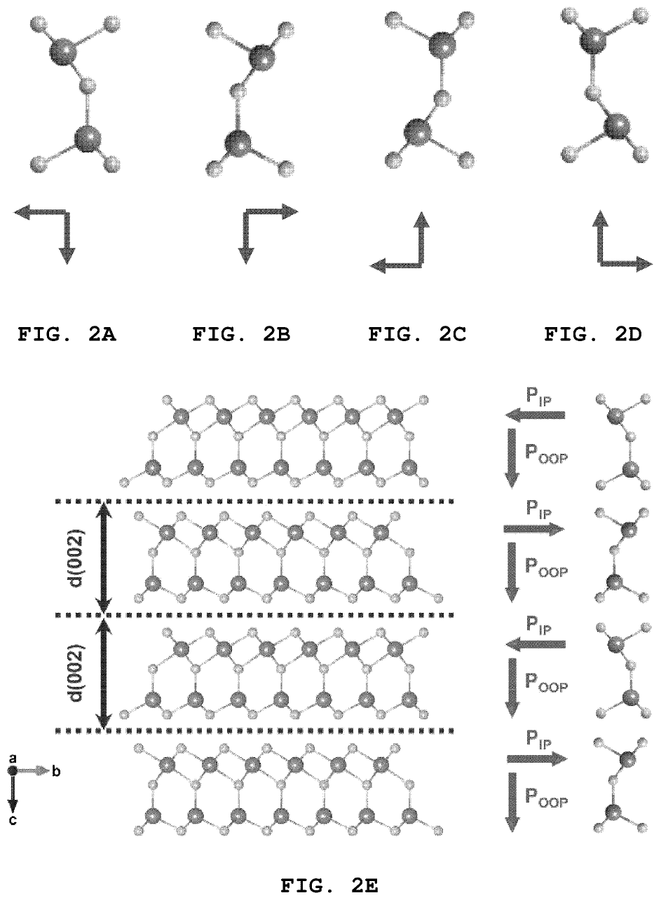

FIGS. 2A to 2E are conceptual views illustrating crystal structures and polarization phenomena of a two-dimensional ferroelectric material used in the synaptic device according to the exemplary embodiment.

The exemplary embodiment in FIGS. 2A to 2E illustrates an example of a case where indium (II) selenide (In₂Se₃) is used as a two-dimensional ferroelectric material. Here, blue spheres represent indium (In) atoms in group 3 of the periodic table, and yellow atoms represent selenium (Se) atoms in group 6. Alpha (a) phase indium selenide (In₂Se₃) has a structure in which two layers of a 2H hexagonal structure are alternately stacked. Alpha indium selenide (α-In₂Se₃) may be separated into plates and used as a two-dimensional ferroelectric semiconductor.

FIGS. 2A to 2D illustrate four polarization states of an indium selenide crystal. The arrows below each crystal structure represent polarization vector components in each case.

FIG. 2E shows a state in which alpha indium selenide (α-In₂Se₃) is stacked, as viewed from a side (in a red α-axis direction in a coordinate system depicted on a lower left side of FIG. 2E). From the bottom, a layer in the form in FIG. 2B and a layer in the form in FIG. 2A are alternately stacked. The polarization in a left-right direction (i.e., a green b-axis direction in the coordinate system on the lower left side) alternates, in other words, the polarization parallel to the stacked planes (i.e., in-plane, IP) direction (PIP) alternates, so the polarization cancels each other out and becomes zero overall. The polarization in a top-down direction (i.e., a blue c-axis direction in the coordinate system on the lower left side) is in the same downward direction, in other words, the polarization perpendicular to the stack planes (i.e., out-of-plane, OOP) direction (POOP) is in the same downward direction, so alpha indium selenide (α-In₂Se₃) may be used as a ferroelectric material. When the crystal structures of layers in the forms of FIGS. 2B and 2A are changed to the crystal structures of layers in the forms of FIGS. 2C and 2D by an external electric field, a polarization component in a direction perpendicular to the stacked planes is reversed from down to up.

Meanwhile, indium selenide (α-In₂Se₃) is a compound of indium (In), which belongs to a post-transition metal, and selenium (Se), which is a group-16 element called a chalcogen, thereby corresponding to a post-transition metal dichalcogenide (Post-TMDC). The above post-transition metal dichalcogenide is a compound similar to a transition metal dichalcogenide (TMDC) to be described below, and has similar physical or chemical properties thereof. The transition metal dichalcogenide (TMDC) is a material having a two-dimensional layered structure that form strong covalent bonds between atoms in the same layer and weak van der Waals bonds between layers. The transition metal dichalcogenide (TMDC) has the properties of having no unsaturated bond (i.e., no dangling bond) on a plane and a direct bandgap in a single layer. The indium selenide (α-In₂Se₃), which is a transition metal dichalcogenide, differentiates it from typical TMDC compounds to exhibit the properties of the direct band gap even in a multilayer state. In this way, the indium selenide with the two-dimensional structure has excellent electrical and optical properties. In addition to the indium selenide (α-In₂Se₃), the post-transition metal dichalcogenide (Post-TMDC) includes similar compounds such as bismuth oxyselenide (Bi₂O₂Se).

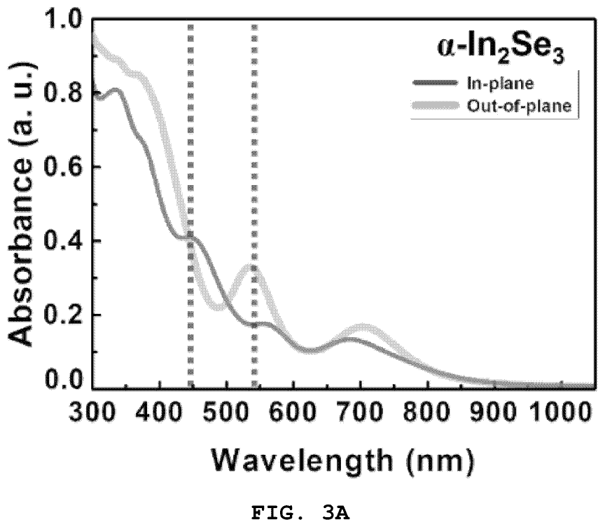

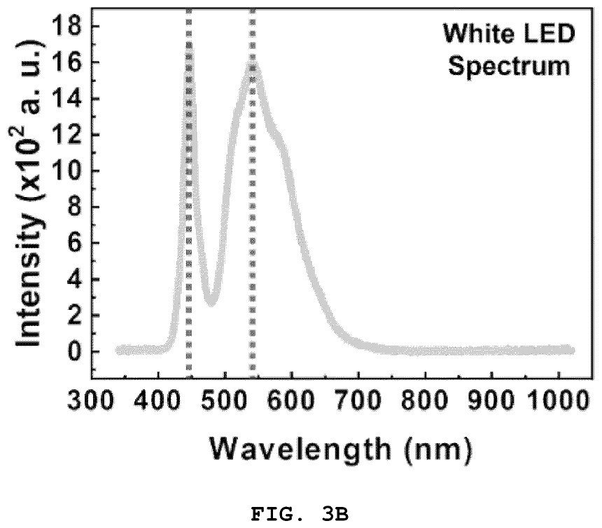

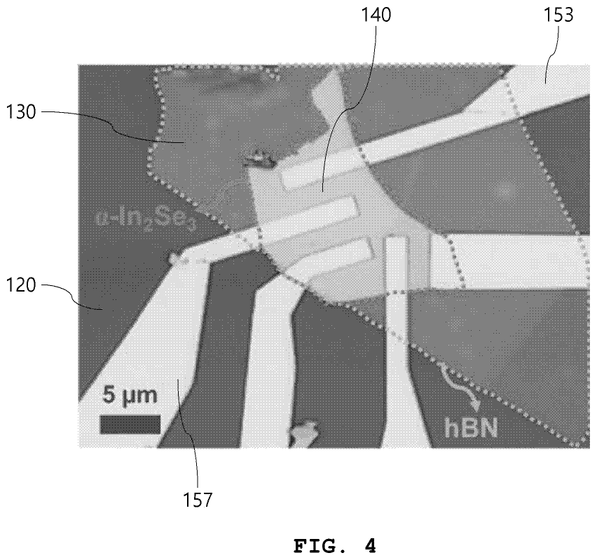

FIGS. 3A and 3B are graphs illustrating optical properties of the ferroelectric material used in the neuromorphic synaptic device according to the exemplary embodiment.

FIG. 3A illustrates the degree of light absorption according to the wavelengths of indium selenide (α-In₂Se₃). A gray line represents absorption in a direction parallel to stacked planes, and a green line represents the degree of absorption in a direction perpendicular to the stacked planes.

FIG. 3B illustrates light intensities depending on wavelengths of a white light LED. The white light LED has peak light intensities (at red dotted lines) around 450 nm and 550 nm.

Referring to FIG. 3A, the indium selenide (α-In₂Se₃) may absorb the peak wavelengths of the white light LED in the direction perpendicular to the stacked planes. Meanwhile, in FIG. 3A, the indium selenide (α-In₂Se₃) also absorbs light below 400 nm well, so a mercury lamp having peak wavelengths between 300 nm and 400 nm may be used instead of the white light LED. In the following, the white light LED is used to illuminate a ferroelectric semiconductor with light, but various lamps, such as the mercury lamp, for providing light of UV (ultra-violet) wavelengths that may be absorbed by the ferroelectric semiconductor may be used.

FIG. 4 is a photograph taken from above with a microscope for the neuromorphic synaptic device according to the exemplary embodiment. Each layer constituting the synaptic device is shown in the photograph.

A highly doped silicon (p⁺⁺ Si) substrate is used as a gate electrode layer 110 for the synaptic device. The highly doped silicon (p⁺⁺ Si) substrate is connected to a device that applies a gate voltage, thereby transmitting the gate voltage to the synaptic device.

A barrier insulating layer 120 is formed on the substrate. The barrier insulation layer 120 corresponds to a brown area in the photograph. The barrier insulating layer 120 may be composed of an oxide such as silicon dioxide (SiO₂).

A buffer insulation layer 130 is formed on the barrier insulation layer. The buffer insulation layer 130 corresponds to a green area in the photograph. The buffer insulating layer 130 uses hexagonal boron nitride (hBN) having a thickness of approximately 20 nm. The hexagonal boron nitride (hBN) may be formed by using mechanical exfoliation. The hexagonal boron nitride (hBN) has no dangling bond on a plane thereof and is very flat, thereby allowing it to retain the properties of two-dimensional materials layered on top thereof.

A channel layer 140 is formed on the buffer insulation layer. The channel layer 140 corresponds to a yellow area surrounded by a red dotted line in the photograph. Multilayer indium selenide (α-In₂Se₃), which is a ferroelectric semiconductor having a thickness of approximately 50 nm, is used as the channel layer 140. The indium selenide (α-In₂Se₃) may be formed by using mechanical exfoliation. In addition to the indium selenide (α-In₂Se₃), bismuth oxyselenide (Bi₂O₂Se), which is a post-transition metal dichalcogenide (Post-TMDC), may be used as the channel layer.

A plurality of electrodes 153 and 157 is formed on the channel layer. The electrodes correspond to yellow areas in the photograph. The electrodes are formed spaced apart from each other on the channel layer. Each electrode may be formed by depositing 5 nm of chromium (Cr) and 100 nm of gold (Au). One electrode may be used as a source electrode 153, and the other electrode spaced apart from the one electrode may be used as a drain electrode 157.

The indium selenide (α-In₂Se₃)-based ferroelectric field effect transistor (FeFET) fabricated in FIG. 4 has multiple ferroelectric properties and may be used as a synaptic memory. An E² (˜87.6 cm⁻¹) peak indicating a 2H hexagonal structure of indium selenide is illustrated in an Raman spectrum of an indium selenide (α-In₂Se₃) layer inside the fabricated FeFET synaptic device, and an interlayer distance d(002) between the stacked layers of the indium selenide (α-In₂Se₃) is measured to be approximately 0.976 nm by high-resolution transmission electron microscopy (HR-TEM).

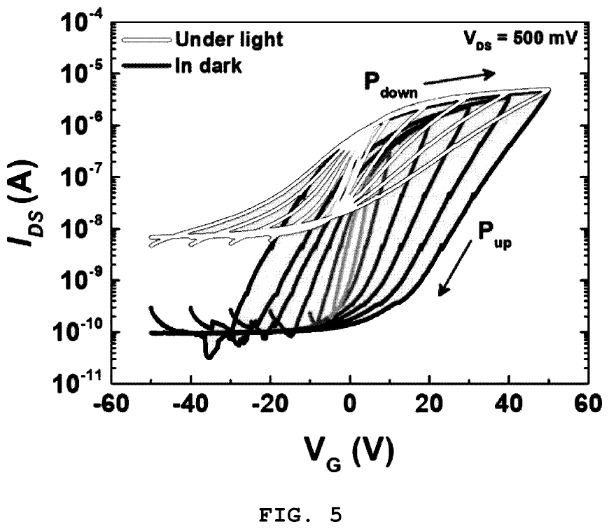

FIG. 5 is a graph illustrating direct measurement of a source-drain current I_{DS} according to controlling of a gate voltage V_{G} of the neuromorphic synaptic device according to the exemplary embodiment.

A transfer curve graph in FIG. 5 is obtained by applying a voltage V_{DS} of 500 mV between the source and drain electrodes of the neuromorphic synaptic device in FIG. 4 and measuring the current I_{DS} flowing between the source electrode and the drain electrode. The transfer curve graph is obtained by measuring a gate voltage V_{G} while varying a range thereof from ±5 V to ±50 V. A blue-series graph illustrates a result obtained by performing the measurement in dark, and a red-series graph is a result obtained by performing the measurement under white LED light for illumination. In the graph, a behavior of electrical hysteresis curve in a clockwise direction due to a polarization delay in a direction perpendicular to the stacked planes of indium selenide (α-In₂Se₃) may be confirmed, and the properties of a corresponding memory window (MW) that widens as the range of gate voltage increases may be confirmed.

In the source-drain electrical characteristic curve according to the gate voltage in FIG. 5, when the polarization Pᵤₚ of indium selenide is upward, an off-current level indicating the lowest current flow between the source electrode and drain electrode in the gate voltage V_{G} range of −50 to 0 V is at a level of 10⁻¹⁰ A in a dark state, and increases to a level of 10⁻⁸ A in a case of illumination with light. In contrast, in the case of being in the dark and in the case of illumination with light, the widths of memory window (MW) are almost similar to each other regardless of whether the illumination with light is present or not.

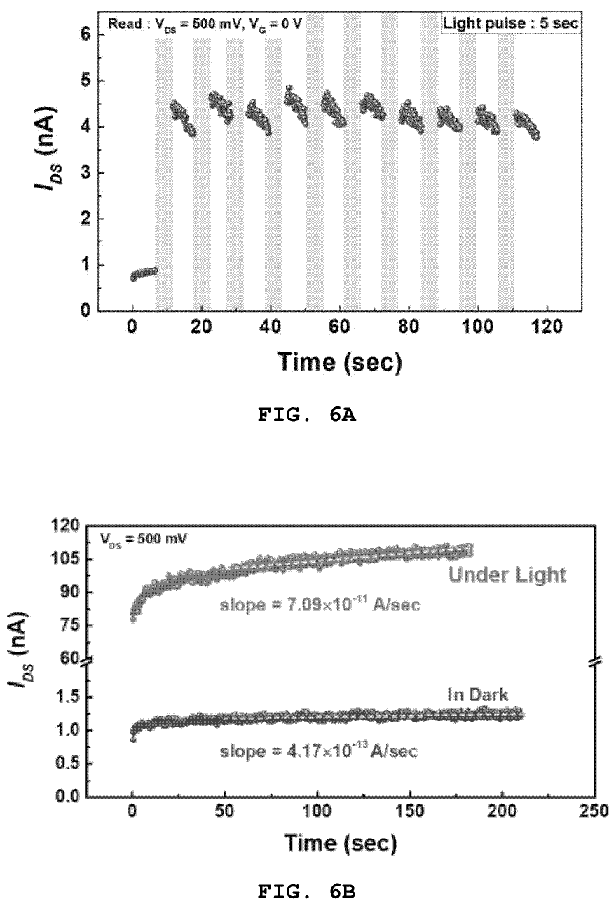

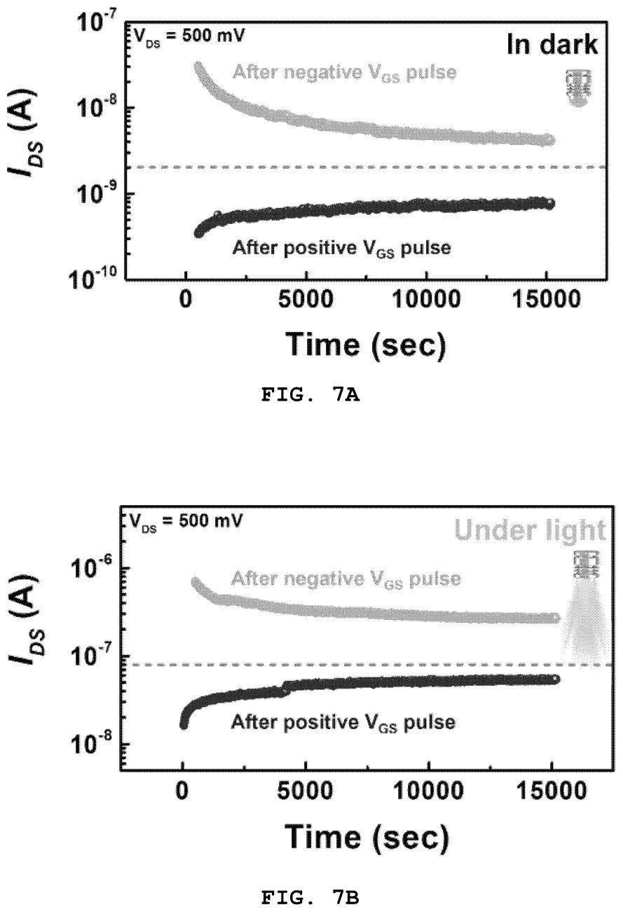

FIGS. 6A and 6B are graphs illustrating electrical responses to light stimulation of the neuromorphic synaptic device according to the exemplary embodiment.

The graphs in FIGS. 6A and 6B are obtained by measuring a current I_{DS} flowing between the source electrode and the drain electrode at V_{DS}=500 mV when light stimulation with a predetermined width is periodically applied at a predetermined time interval to the indium selenide-based neuromorphic synaptic device shown in FIG. 4. When the light stimulation is applied, no external voltage is applied at all, and after the illumination with light is finished, the voltage V_{DS} of 500 mV is applied between the source electrode and the drain electrode, and no voltage is applied to the gate electrode.

FIG. 6A is a graph illustrating results of illumination with light pulses for five seconds at an intensity of 1 mWcm⁻² and measurement with an interval between pulses that is set to six seconds. Areas indicated with yellow pillars are areas illuminated with light, and measured data is marked with purple dots. The purple dots on the far left, in a range of 0.5 nA to 1.0 nA, indicate currents flowing in a dark state due to a V_{DS} bias. After the illumination is performed with the light pulses, an amplified long-term potentiation (LTP) current in a range of 3.5 nA to 5.0 nA is detected, even when no electrical pulses are applied.

FIG. 6B illustrates results of measurements taken in a dark place and in a place under continuous illumination with light. Black dots at a lower side are results of continuous measurements of I_{DS} in the dark, and red dots at an upper side are results of continuous measurement of I_{DS} in the state of continuous illumination with light.

The black dots at the lower side show almost constant values, so it may be determined that the current I_{DS} in the dark does not change much depending on measurement time therefor. The I_{DS} in the dark is measured in a range of 0.8 nA to 1.0 nA for approximately 200 seconds, and a slope thereof is 4.17×10⁻¹³ A/sec.

The red dots at the upper side are gradually increasing and becoming saturated, which is due to the influence of a built-in electric field F_{bi} induced by the illumination with light. This is measured in a range of 80 nA to 105 nA for approximately 200 seconds, and a slope thereof is 7.09×10⁻¹¹ A/sec. This value may be used as a reference value for an equilibrium polarization state of indium selenide (α-In₂Se₃) for photo-induced postsynaptic current (PSC).

FIGS. 7A and 7B are graphs illustrating retention properties over time for electrical stimulation of the neuromorphic synaptic device according to the exemplary embodiment.

Each of the graph in FIGS. 7A and 7B is obtained by applying a voltage V_{DS} of 500 mV between the source electrode and drain electrode of the neuromorphic synaptic device in FIG. 4 and measuring a current I_{DS} flowing between the source electrode and the drain electrode. For potentiation, a pulse with a gate spike voltage V_{GS} of −40 V and a width of 5 seconds is applied 10 times, and for depression, a pulse with a gate spike voltage V_{GS} of +40 V and a width of 5 seconds is applied 10 times. The results obtained by the potentiation (negative (−) voltage) are shown in an upper-side orange graph, and the results obtained by the depression (positive (+) voltage) are shown in a blue graph at a lower side.

FIG. 7A is a graph obtained by measurement in dark, and FIG. 7B is a graph obtained by measurement while performing illumination with light by using a white light LED. For sufficient time periods of more than 15,000 seconds, the currents I_{DS} generated by negative pulses (potentiation indicated in orange) and positive pulses (depression indicated in blue) are retained regardless of the presence or absence of illumination. Meanwhile, the degrees of electric current retention after a predetermined period of time are different from each other between that in FIG. 7A without light and that in FIG. 7B with light. In addition, there is a difference in the degrees of change in potentiation and depression for the same magnitude of gate spike voltages V_{GS}. The degree of electric current retention in the state of long-term depression (LTD) in the case of FIG. 7B obtained by measurement under the illumination with light is shown to be relatively much shorter than that in FIG. 7A obtained by measurement in the dark. This may be caused by the influence of a downward built-in electric field that is generated when the illumination with light is performed into the indium selenide.

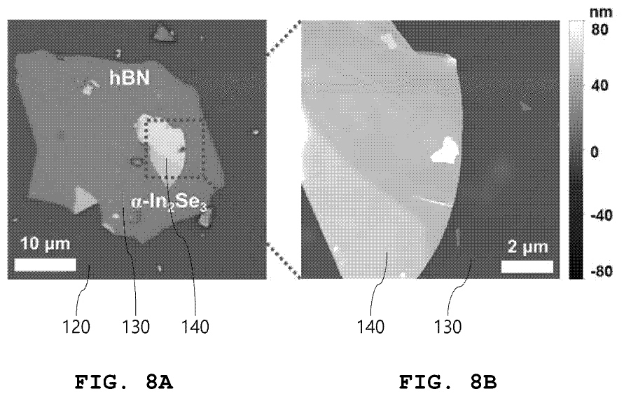

FIGS. 8A and 8B are topography photographs obtained by measurement using an optical microscope and an atomic force microscope (AFM) for indium selenide (α-In₂Se₃), which is a ferroelectric semiconductor, according to the exemplary embodiment.

FIG. 8A is the optical microscope photograph of the synaptic device in FIG. 4 excluding the electrodes. A buffer insulating layer 130 made of hexagonal boron nitride (hBN) is positioned on a barrier insulating layer 120 made of silicon dioxide (SiO₂), and a channel layer 140 made of indium selenide (α-In₂Se₃) is positioned on the buffer insulating layer.

FIG. 8B is an AFM topography image of a channel layer 140 made of indium selenide (α-In₂Se₃) as well as the buffer insulating layer 130 made of the hexagonal boron nitride (hBN). It may be seen from the topography that each of the channel layer 140 and the buffer insulation layer 130 is formed with a uniform thickness.

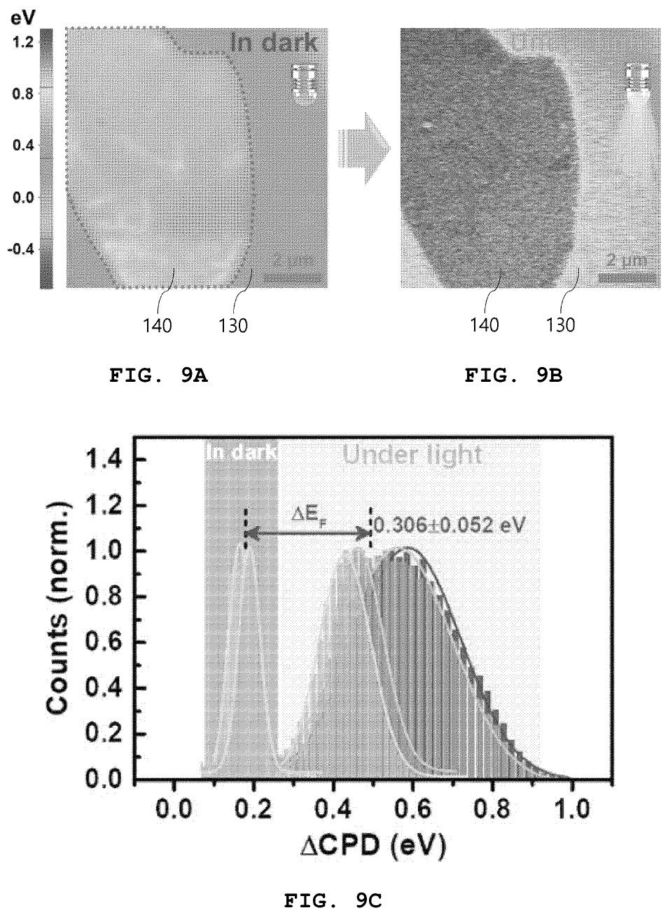

FIGS. 9A to 9C are photographs and a graph illustrating the distribution of plane potential and contact potential difference in a dark state or under a state of illumination with light for indium selenide (α-In₂Se₃), which is a ferroelectric semiconductor, as measured by a scanning Kelvin probe microscope according to the exemplary embodiment.

FIGS. 9A and 9B are images illustrating a contact potential difference (CPD) of the channel layer 140 made of the indium selenide (α-In₂Se₃), which is the ferroelectric semiconductor in FIGS. 8A and 8B, as measured by using the scanning Kelvin probe microscope (SKPM). FIG. 9A shows a result measured in a place without light, and FIG. 9B shows a result measured while performing illumination with light.

FIG. 9C illustrates a difference ΔCPD obtained by subtracting a contact potential difference CPD_{hBN} of the hexagonal boron nitride (hBN) from a contact potential difference CPD_{channel layer} of the indium selenide (α-In₂Se₃), which is measured in FIGS. 9A and 9B. A green peak in a gray area on the left corresponds to FIG. 9A without light, and an orange peak in a yellow area on the right corresponds to FIG. 9B with light. A change in Fermi energy ΔE_{F} due to the illumination with light is measured as 0.306±0.052 eV.

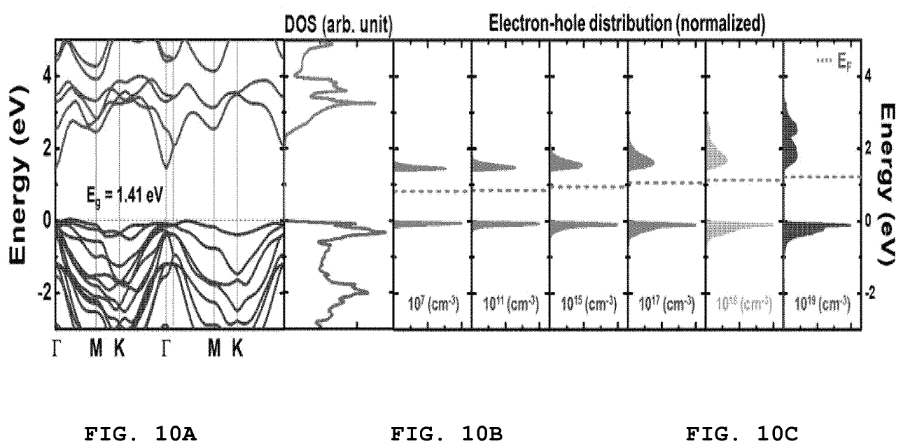

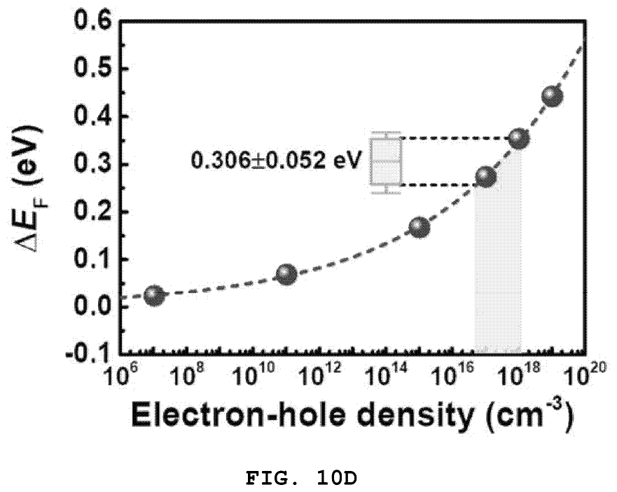

FIGS. 10A to 10D are graphs illustrating an energy band structure and state densities for indium selenide (α-In₂Se₃), which is a ferroelectric semiconductor applied as a channel layer of the synaptic device according to the exemplary embodiment.

Energy states in FIGS. 10A to 10D are energy states of the indium selenide (α-In₂Se₃) forming the channel layer of the synaptic device in FIGS. 8A and 8B. FIG. 10A illustrates the energy band structure, FIG. 10B illustrates the density of states (DOS), and FIG. 10C illustrates electron-hole distribution.

In FIG. 10C, a horizontal dotted line represents Fermi Energy E_{F} or a Fermi Level. As the intensity of light used to illuminate the channel layer increases, an electron-hole density increases from 10⁷ cm⁻³ on the left to 10¹⁹ cm⁻³ on the right. As the electron-hole density increases, the Fermi energy increases due to the asymmetric density of states between a conduction band (CB) and a valence band (VB).

FIG. 10D shows changes in Fermi energy ΔE_{F} depending on the electron-hole densities obtained from FIG. 10C. The changes in Fermi energy ΔE_{F} of 0.306±0.052 eV obtained in FIGS. 9A to 9C correspond to photoinduced charge carrier densities in a range of 4.8×10¹⁶ cm⁻³ to 1.3×10¹⁸ cm⁻³ in FIG. 10D. Accordingly, under white light, the Fermi energy E_{F} increases significantly to about 300 meV due to the unequal energy level occupancy of electrons and holes in the indium selenide (α-In₂Se₃) channel layer 140 at an exciton density of about 10¹⁸ cm⁻³.

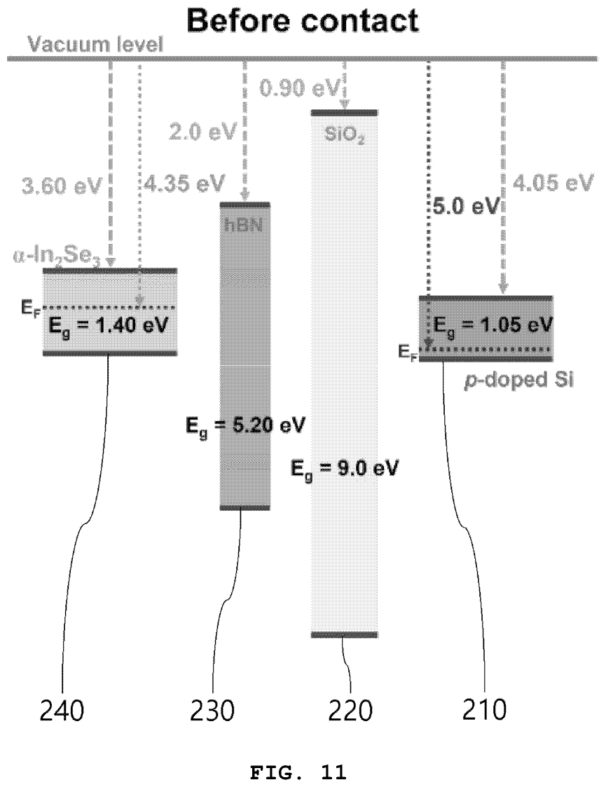

FIG. 11 is a band diagram illustrating energy levels of each layer of the neuromorphic synaptic device before contact according to the exemplary embodiment.

From the right, FIG. 11 illustrates each energy band including: an energy band 210 of the gate electrode layer composed of p-doped silicon (Si); an energy band 220 of the barrier insulating layer composed of silicon dioxide (SiO₂); an energy band 230 of the buffer insulating layer composed of hexagonal boron nitride (hBN); and an energy band 240 of the channel layer composed of indium selenide (α-In₂Se₃).

The energy band 210 of the gate electrode layer and the energy band 240 of the channel layer have Fermi energy E_{F} each indicated by a red dotted line. The Fermi energy of the gate electrode layer is 5.0 eV, and the Fermi energy of the channel layer is 4.35 eV.

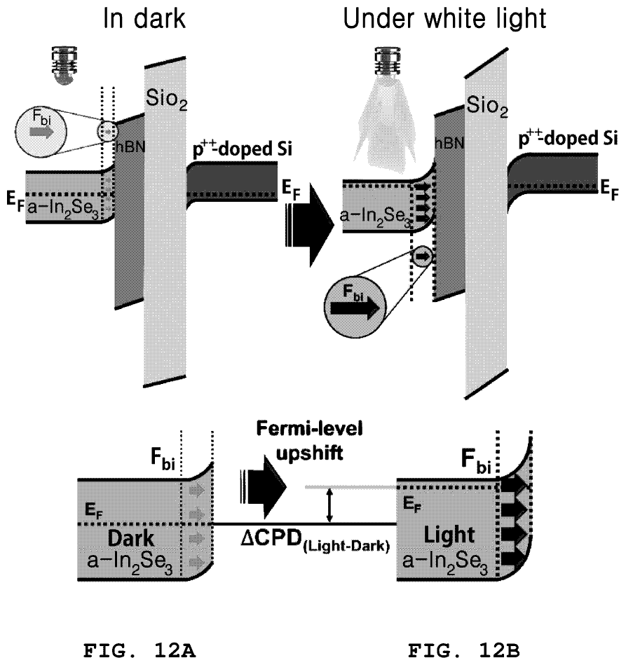

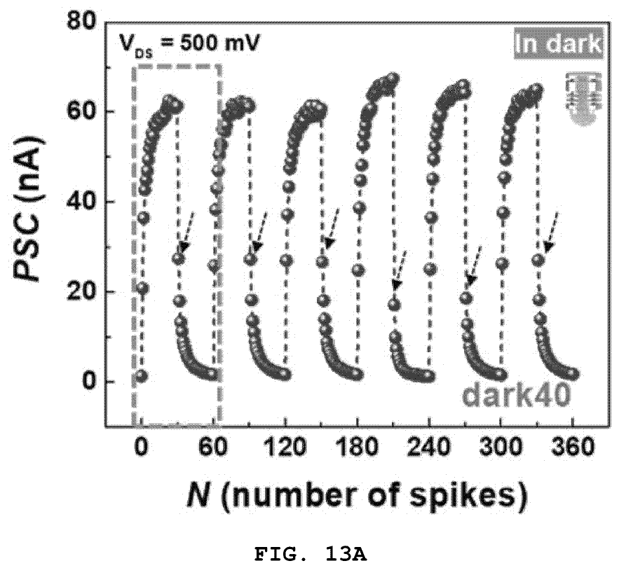

FIGS. 12A and 12B are band diagrams each illustrating an energy level after each layer of the synaptic device is in contact according to the exemplary embodiment.

FIG. 12A is an energy band diagram in a case of no illumination with light, and FIG. 12B is an energy band diagram in a case of illumination with light.

In FIG. 12A, when each layer comes into contact with another, the Fermi energies of each layer is aligned with each other to achieve thermal equilibrium. As a result, an internal electric field F_{bi} is generated in each depletion layer area of the gate electrode layer and the channel layer.

In FIG. 12B, in a case of illuminating the channel layer of the ferroelectric material with light, the Fermi energy of the channel layer increases as in FIGS. 10A to 10D. As a result, in the case of illuminating the channel layer with light, a large difference in the positions of the Fermi energies occurs between the gate layer and the channel layer, and due to this difference, the internal electric field F_{bi} becomes stronger.

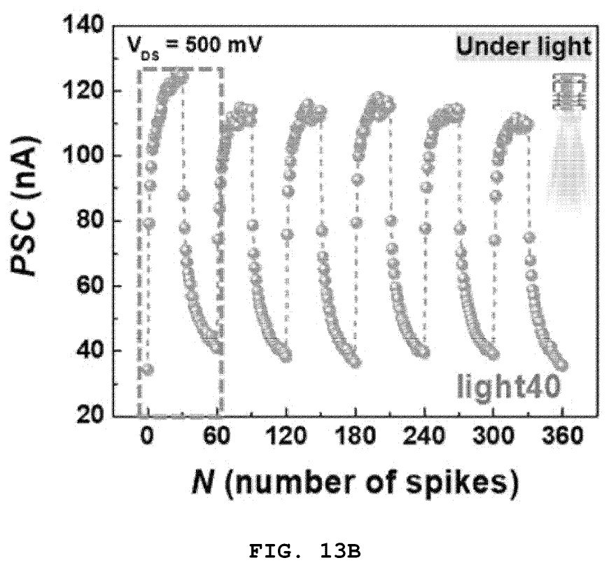

FIGS. 13A and 13B are graphs illustrating the properties of weight potentiation and weight depression for high gate spike voltage of the neuromorphic synaptic device according to the exemplary embodiment.

When a presynaptic spike signal is input to the gate electrode of the synaptic device, a postsynaptic current (PSC) is output between the source and drain electrodes of the synaptic device. At this time, a current value corresponding to a weight is measured by applying a bias voltage of V_{DS}=500 mV between the source electrode and the drain electrode.

The postsynaptic current (PSC) of the synaptic device is measured for processes of long-term potentiation (LTP) and long-term depression (LTD), each consisting of 30 pulses (spikes) for weight potentiation and weight depression. Accordingly, the postsynaptic current (PSC) exhibits a waveform repeating six times in total with a 60-pulse cycle.

For the long-term potentiation (LTP), 30 pulses with a gate spike voltage V_{GS} of −40 V and a pulse width of 5 s are input, and for the long-term depression (LTD), 30 pulses with a gate spike voltage V_{GS} of ±40 V and a pulse width of 1 ms are input. Since the relaxation properties of the synaptic device differ in potentiation and depression, pulse widths different from each other are set for the long-term potentiation (LTP) and the long-term depression (LTD).

FIG. 13A is a graph illustrating a postsynaptic current (PSC) in a case of no illumination with light (indicated as “dark40”). In FIG. 13A, a black arrow indicates a position where long-term potentiation (LTP) is transitioned to long-term depression (LPD). At this position, a postsynaptic current (PSC) changes abruptly from about 65 nA to about 25 nA, resulting in a postsynaptic current (PSC) drop rate of about 60%. Although the pulse width of long-term depression (LPD) for weight depression is much shorter than that of long-term potentiation (LTP) for weight potentiation, a rapid synaptic current drop occurs at the beginning of the long-term depression (LPD).

Meanwhile, in a case where the gate spike voltage V_{GS} is reduced, a rapid change in the long-term depression (LPD) in the postsynaptic current (PSC) is reduced, but a problem arises that a ratio (Gₘₐₓ/Gₘᵢₙ) of the maximum conductance to the minimum conductance, indicating a magnitude of synaptic plasticity, is reduced.

FIG. 13B is a graph illustrating a postsynaptic current (PSC) in a case of continuous illumination with light (indicated as “light40”). Although the linearity is improved compared to that in FIG. 13A, a synaptic current drop rate at a position where the weight potentiation process is transitioned to the weight depression process is still large.

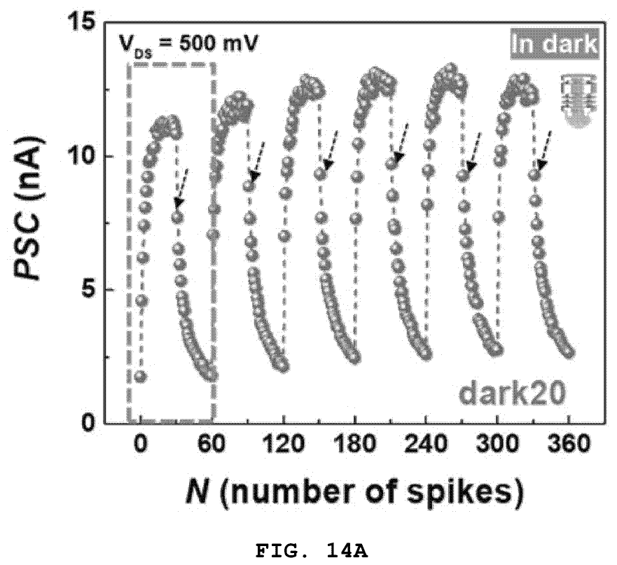

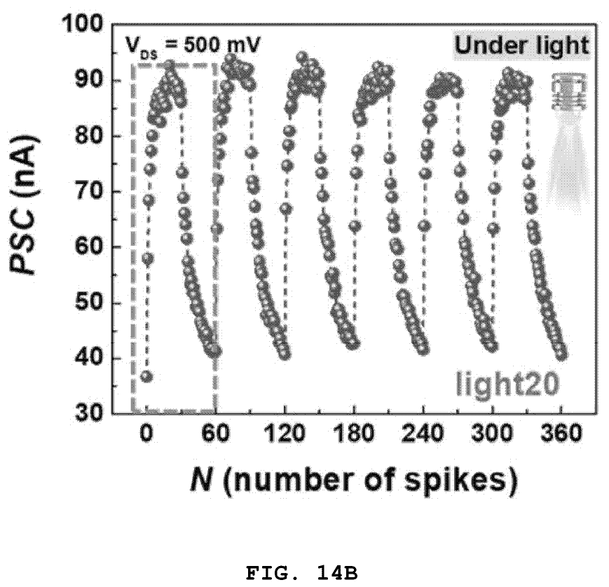

FIGS. 14A and 14B are graphs illustrating the properties of weight potentiation and weight depression for optimal gate spike voltage of the neuromorphic synaptic device according to the exemplary embodiment.

The gate spike voltage V_{GS} is optimized to ±20V in order to increase the linearity of postsynaptic current (PSC), that is, in order to increase the linearity especially by further alleviating the synaptic current drop in the weight depression process through the long-term depression (LPD), and to retain an appropriate ratio (Gₘₐₓ/Gₘᵢₙ) of the maximum conductance to the minimum conductance. In addition, the pulse width of the gate spike is also controlled. That is, for long-term potentiation (LTP), 30 pulses with a gate spike voltage V_{GS} of −20 V and a pulse width of 2 s are input, and for long-term depression (LTD), 30 pulses with a gate spike voltage V_{GS} of ±20 V and a pulse width of 0.1 ms are input.

FIG. 14A is a graph illustrating a postsynaptic current (PSC) through a series of weight potentiation and weight depression in a case of no illumination with light (indicated as “dark20”). In FIG. 14A, a black arrow indicates a position where a weight potentiation process through long-term potentiation (LTP) is transitioned to weight depression through long-term depression (LTD). At this position, the postsynaptic current (PSC) changes from approximately 12 nA to approximately 8 nA, resulting in a postsynaptic current (PSC) drop rate of approximately 30%. This is a much improved value than that in FIG. 13A. However, as the maximum postsynaptic current (PSC) decreases to approximately 12 nA, the magnitude of synaptic plasticity is reduced.

FIG. 14B is a graph illustrating a postsynaptic current (PSC) through a series of weight potentiation and weight depression in a case of continuous illumination with light (indicated as “light20”). In the case of the illumination with light, the maximum postsynaptic current (PSC) increases to the level of approximately 90 nA. In addition, in the case of the illumination with the light, the linearity of the weight potentiation through long-term potentiation (LTP) as well as the weight depression through long-term depression (LPD) may be improved while retaining the synaptic plasticity.

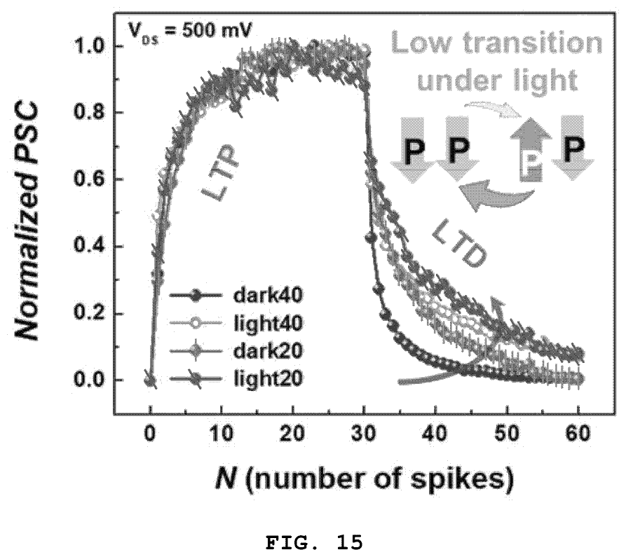

FIG. 15 is a graph comparing postsynaptic currents for various gate spike voltages of the neuromorphic synaptic device according to the exemplary embodiment.

FIG. 15 illustrates all the graphs of boxes indicated by black dotted lines in the graphs of FIGS. 13A to 14B together. The vertical axis is indicated as a normalized value for each graph.

In FIG. 15, in weight potentiation sections through long-term potentiation (LTP), all the results show similar patterns, but in weight depression sections through long-term depression (LTD), the linearity is improved in the order of dark40 (blue), dark20 (green), light40 (orange), and light20 (red) cases. In the case where the ferroelectric material of the synaptic device is illuminated with light, the linearity is improved because low transition from potentiation P_{down} to depression Pᵤₚ occurs during the weight depression process through the long-term depression (LTD) due to the downward polarization induced by the internal electric field F_{bi}.

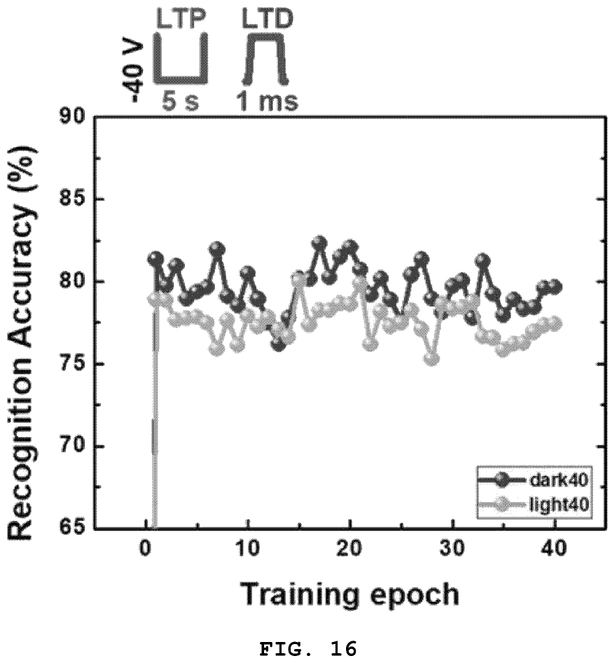

FIG. 16 is a simulation graph illustrating recognition accuracy of digits for high gate spike voltage of the neuromorphic synaptic device according to the exemplary embodiment.

The recognition accuracy of synaptic device is evaluated through classification simulation on handwritten digit data from a database called Modified National Institute of Standards and Technology (MNIST) DB. The simulation is performed by using a CrossSim platform released by Sandia National Laboratories. Since the MNIST data is composed of 28*28=784 pixels, 784 input neurons are used and 10 output neurons are used to output digit classification results. An artificial neural network is created by arranging 300 hidden neurons between the input neurons and the output neurons, and arranging, between the neurons, the synaptic devices to which weights are applied. The artificial neural network is trained with 60,000 MNIST images, and a recognition rate thereof is tested on 10,000 images. A training rate for the image recognition is set to 0.1, and a training epoch is 40. The recognition accuracy is evaluated by performing simulation for six cycles of weight potentiation through long-term potentiation (LTP), consisting of 60 cycles, followed by weight depression through long-term depression (LTD).

FIG. 16 is a graph illustrating recognition accuracy in a case where gate spike voltage V_{GS} is ±40V. For other conditions, see the description in FIGS. 13A and 13B. In FIG. 16, recognition accuracy in a case of no light (dark40) is approximately 79.2%, and recognition accuracy in a case of presence of light (light40) is approximately 77.6%, showing a value almost similar to that in the case of no light (dark40).

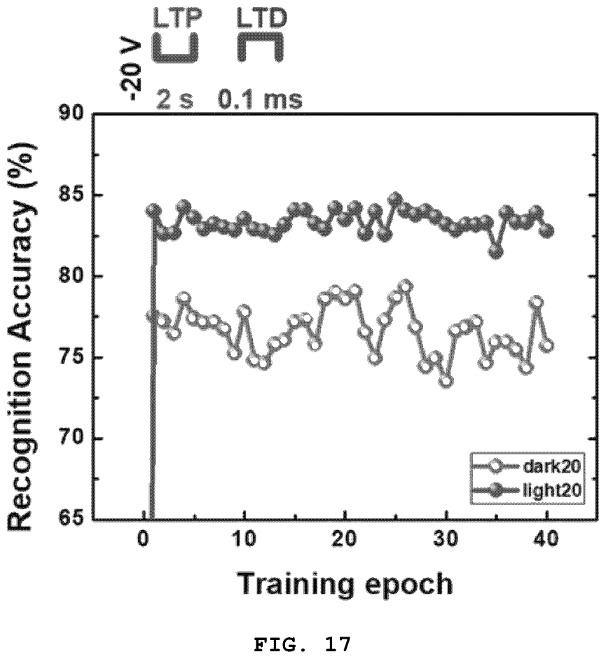

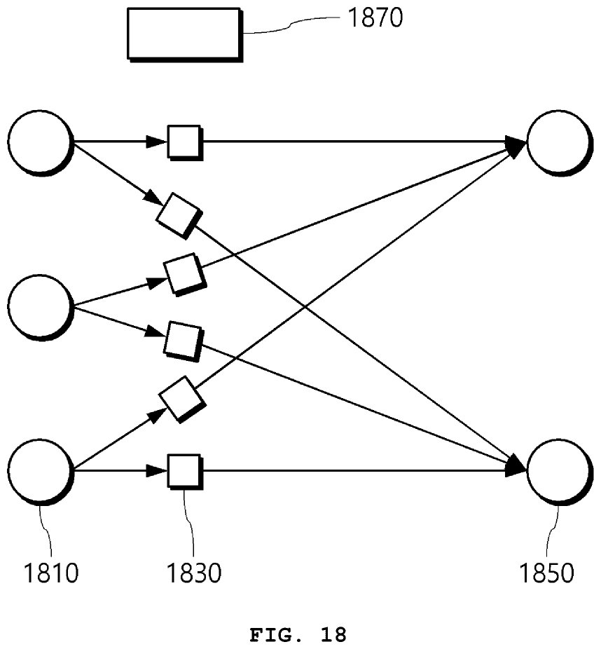

FIG. 17 is a graph illustrating recognition accuracy of digits for optimal gate spike voltage of the neuromorphic synaptic device according to the exemplary embodiment.

FIG. 17 is the graph illustrating the recognition accuracy in a case where the gate spike voltage V_{GS} is ±20V. For other conditions, see the description in FIGS. 14A and 14B. In FIG. 17, recognition accuracy in a case of no light (dark20) is approximately 76.4%, showing that the recognition accuracy compared to the result in FIG. 16 is not improved. However, in FIG. 17, recognition accuracy in a case of presence of light (light20) is approximately 84%, showing the recognition accuracy better than the result in FIG. 16. Accordingly, in the case of illuminating the synaptic device with light and with a gate spike voltage V_{GS} having an appropriate width, it is able to improve the recognition accuracy of the MNIST digits.

When the indium selenide (α-In₂Se₃) ferroelectric channel layer is illuminated with light, an exciton (i.e., an electron-hole pair) density increases and a Fermi level E_{F} increases. Due to the increase of the Fermi level, an enhanced internal electric field F_{bi} is generated in a ferroelectric channel layer area in a bonding structure from a ferroelectric channel layer to a p⁺-type gate electrode layer. Since the enhanced internal electric field F_{bi} continuously induces downward polarization P_{down} on one side, the transition to the opposite polarization Pᵤₚ is reduced, whereby a drop rate of postsynaptic current (PSC) may be lowered during weight depression process through long-term depression (LTD). In contrast, when illumination is performed with light, the overall postsynaptic current (PSC) increases, thereby reducing the magnitude of synaptic plasticity. Accordingly, the optimal gate spike voltage V_{GS} may be determined by considering Gₘₐₓ/Gₘᵢₙ values, nonlinearity of the series of weight potentiation and weight depression cycles, periodic changes, etc.

FIG. 18 is a schematic diagram illustrating a configuration of an artificial neural network module using synaptic devices according to the exemplary embodiment.

According to another aspect of the proposed disclosure, an artificial intelligence module using a high-performance photoactive synaptic device using a ferroelectric semiconductor with an asymmetric energy band structure includes a synaptic device 1830 and a light illumination device 1870. The artificial intelligence module further includes a presynaptic neuron circuit 1810 and a postsynaptic neuron circuit 1850.

The presynaptic neuron circuit 1810 may include a pulse generator (not shown). The pulse generator (not shown) generates spike pulses to a gate electrode of the synaptic device 1830. The pulse generator (not shown) generates a first pulse having a first pulse width in a weight potentiation section and generates a second pulse having a second pulse width in a weight depression section. The voltage amplitudes of the first and second pulses may be identical. It is preferable that time widths of the first and second pulses be different from each other. Accordingly, the pulses input to the gate electrode of the synaptic device 1830 have the first pulse width in the weight potentiation section and the second pulse width different from the first pulse width in the weight depression section.

In a case of using the synaptic device 1830 using a hexagonal boron nitride (hBN) buffer insulating layer and an indium selenide (α-In₂Se₃) channel layer, it is preferable that when generating a second pulse in a weight depression section, the pulse generator generates a width of the second pulse to be shorter than a width of a first pulse in a weight potentiation section. For example, the first pulse width may be set to 2 s, and the second pulse width may be set to 0.1 ms, which is shorter than the first pulse width.

The postsynaptic neuron circuit 1850 may include a summing circuit (not shown). The summing circuit (not shown) may sum and store postsynaptic currents (PSCs) of a plurality of synaptic devices 1830. The postsynaptic neuron circuit 1850 may be configured with the same circuit as that of the presynaptic neuron circuit 1810.

The light illumination device 1870 performs illumination with light in a range of visible light or ultraviolet light toward a channel layer of the synaptic device 1830. The linearity of postsynaptic current (PSC) is improved during a weight depression process of the synaptic device 1830 by the light illumination device 1870.

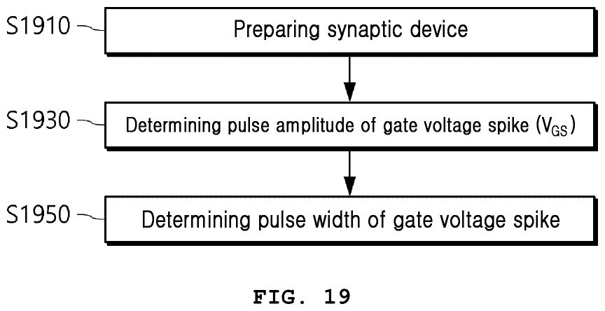

FIG. 19 is a flowchart illustrating a method of designing an artificial neural network module using neuromorphic synaptic devices according to the exemplary embodiment.

According to another aspect of the proposed disclosure, a method of designing an artificial intelligence module using a high-performance photoactive synaptic device using a ferroelectric semiconductor with an asymmetric energy band structure includes: step S1910 of preparing a synaptic device; step S1930 of determining a pulse amplitude of a gate voltage spike V_{GS}; and step S1950 of determining a pulse width of the gate voltage spike.

In step S1910 of preparing the synaptic device, a material and thickness of a buffer insulation layer, a material and thickness of a channel layer, etc., which are used in the synaptic device, are determined.

In step S1930 of determining the pulse amplitude of the gate voltage spike V_{GS}, the pulse amplitude of the gate voltage spike V_{GS} is determined based on a ratio (Gₘₐₓ/Gₘᵢₙ) of the maximum conductance to the minimum conductance. To this end, data on the ratio (Gₘₐₓ/Gₘᵢₙ) of the maximum conductance to the minimum conductance according to the pulse amplitude of the gate voltage spike V_{GS} is obtained in advance and a graph is drawn to determine the pulse amplitude of the gate voltage spike V_{GS}. For example, in a Gₘₐₓ/Gₘᵢₙ graph, a voltage at which a slope change is the greatest may be determined as the pulse amplitude of the gate voltage spike V_{GS}.

A pulse amplitude of a gate voltage spike V_{GS} may be determined on the basis of the drop rate of postsynaptic current (PSC). For example, in a graph of the drop rate of postsynaptic current (PSC) according to the pulse amplitude of the gate voltage spike V_{GS}, a pulse amplitude of a voltage at which the corresponding drop rate becomes small may be determined as the pulse amplitude of the gate voltage spike V_{GS}.

The pulse amplitude of the gate voltage spike V_{GS} may be determined based on the ratio (Gₘₐₓ/Gₘᵢₙ) of the maximum conductance to minimum conductance that changes in a case where the channel layer of the synaptic device is illuminated with light.

In step S1950 of determining the pulse width of the gate voltage spike, the pulse width of the gate voltage spike used in long-term potentiation (LTP) and long-term depression (LTD) processes is determined based on a relaxation process of postsynaptic current (PSC). In a case of using the synaptic device using a hexagonal boron nitride (hBN) buffer insulating layer and an indium selenide (α-In₂Se₃) channel layer, it is preferable to generate the pulse width of the gate voltage spike so that a pulse width of a long-term depression (LTD) signal is shorter than a pulse width of a long-term potentiation (LTP) signal.

In the case of illuminating the channel layer of the synaptic device with light, the pulse width of the gate voltage spike may be determined so as to maximally increase linearity, or maximally increase synaptic plasticity for a weight depression section by a long-term depression (LTD) signal.

Although the present disclosure has been described above through the exemplary embodiments referring to the attached drawings, the exemplary embodiments are not limited thereto and should be interpreted to encompass various modified embodiments that may be obviously derived from these exemplary embodiments by those skilled in the art. The scope of the patent claims is intended to encompass these modified embodiments.

What is claimed is:

1. A high-performance photoactive neuromorphic synaptic device using a two-dimensional ferroelectric semiconductor with an asymmetric energy band structure, the synaptic device comprising:
a gate electrode layer;
a buffer insulating layer arranged on the gate electrode layer;
a channel layer arranged on the buffer insulating layer;
a source electrode of a conductor arranged on the channel layer; and
a drain electrode of a conductor arranged on the channel layer and spaced apart from the source electrode,
wherein the channel layer is made of the two-dimensional ferroelectric semiconductor,
the buffer insulating layer is made of an insulating material having a lower dielectric constant than that of the channel layer, and
the gate electrode layer is configured to control an electric field of the channel layer by an applied electrical bias.

2. The synaptic device of claim 1, wherein the channel layer is made of a two-dimensional post-transition metal dichalcogenide.

3. The synaptic device of claim 1, wherein the channel layer is made of either In₂Se₃ or Bi₂O₂Se.

4. The synaptic device of claim 1, wherein the buffer insulating layer is made of either hexagonal boron nitride (hBN) or hexagonal boron carbon nitride (BCN).

5. The synaptic device of claim 1, wherein the gate electrode layer is made of either a metal or a highly doped semiconductor, and has a work function higher than that of the channel layer.

6. The synaptic device of claim 1, wherein the gate electrode layer is configured to control polarization of the channel layer by the applied electrical bias.

7. The synaptic device of claim 1, further comprising:
a barrier insulating layer arranged between the gate electrode layer and the buffer insulating layer.

8. The synaptic device of claim 1, wherein the channel layer is configured to generate electron-hole pairs by absorbing light in a range of visible light or ultraviolet light, and to generate the internal electric field according to increase of a Fermi level.

9. An artificial intelligence module using a high-performance photoactive neuromorphic synaptic device using a two-dimensional ferroelectric semiconductor with an asymmetric energy band structure, the artificial intelligence module comprising:
the synaptic device of claim 1; and
a light illumination device for illuminating light in a range of visible light or ultraviolet light toward the channel layer of the synaptic device.

10. The artificial intelligence module of claim 9, wherein pulses input to a gate electrode of the synaptic device comprise:
a first pulse width in a weight potentiation section by long-term potentiation (LTP); and
a second pulse width different from the first pulse width in a weight depression section by long-term depression (LTD).

11. A method of designing an artificial intelligence module using a high-performance photoactive neuromorphic synaptic device using a two-dimensional ferroelectric semiconductor with an asymmetric energy band structure, the method comprising:
preparing the synaptic device of claim 1;
determining a pulse amplitude of a gate voltage spike (V_{GS}) based on a ratio (Gₘₐₓ/Gₘᵢₙ) of maximum conductance to minimum conductance; and
determining a pulse width of the gate voltage spike used in processes of long-term potentiation (LTP) and long-term depression (LTD) based on a relaxation process of postsynaptic current (PSC).

12. The method of claim 11, wherein the determining of the pulse amplitude of the gate voltage spike (V_{GS}) determines the pulse amplitude of the gate voltage spike (V_{GS}) based on the ratio (Gₘₐₓ/Gₘᵢₙ) of the maximum conductance to the minimum conductance that change in illuminating a channel layer of the synaptic device with light.
